(19) United States
(12) Patent Application Publication
(10) Pub. No.: US 2011/0318607 A1
(43) Pub. Date: Dec. 29, 2011

(54) ALUMINUM ALLOY REFLECTIVE FILM, AUTOMOBILE LIGHT, ILLUMINATOR, ORNAMENTATION, AND ALUMINUM ALLOY SPUTTERING TARGET

(75) Inventors: Nobuhiro Kobayashi, Kobe-shi (JP); Toshiki Sato, Hyogo (JP); Jun Suzuki, Hyogo (JP); Shinichi Tanifuji, Hyogo (JP); Yoshinori Ito, Hyogo (JP); Takayuki Tsubota, Hyogo (JP)

(73) Assignee: Kabushiki Kaisha Kobe Seiko Sho (Kobe Steel, Ltd.), Kobe-shi (JP)

(21) Appl. No.: 13/254,316

(22) PCT Filed: Mar. 2, 2010
(86) PCT No.: PCT/JP2010/053365

§ 371 Date: Sep. 1, 2011

(30) Foreign Application Priority Data
Mar. 2, 2009 (JP) 2009-048222
Sep. 10, 2009 (JP) 2009-209329

(51) Int. Cl. B23P 9/00; C23C 14/34; B05D 1/02; C23C 14/14

(52) U.S. Cl. 428/687; 204/298.13; 427/427

(57) ABSTRACT

Provided is an Al alloy reflective film which does not require a protective film in that it has excellent alkali resistance (resistance to alkali corrosion), acid resistance (resistance to acid corrosion) and humidity resistance (resistance to a high-temperature, humid environment) even if there is no protective film, and which contains 2.5 to 20 at % of at least one element selected from Gd, La, Y, Sc, Tb, Lu, Pr, Nd, Pm, Ce, Dy, Ho, Er, and Tm, with the balance being Al and inevitable impurities. Also provided are an automobile light, illuminator, and ornamentation having such an Al alloy reflective film. Further provided is an Al alloy sputtering target, which is for forming such an Al alloy reflective film and which contains 2.5 to 35 at % of at least one element selected from Gd, La, Y, Sc, Tb, Lu, Pr, Nd, Pm, Ce, Dy, Ho, Er, and Tm, with the balance being Al and inevitable impurities.

### TECHNICAL FIELD

The present invention belongs to a technical field relating to aluminum alloy reflective films, as well as automobile lights, illuminators, ornamentations, and aluminum alloy sputtering targets.

### BACKGROUND ART

Of elements listed in the periodic table, pure aluminum (Al) has a high reflectance (about 88%) and is thereby used as a surface film (coating) of a reflective member in an automobile light. The pure aluminum, however, shows poor corrosion resistance to acids and alkalis because of being an amphoteric metal. The resulting film, when used in an automobile light, deteriorates within a short time and shows a low reflectance. To avoid this problem and to avoid deterioration in reflectance due to corrosion, a protective film is arranged on the film surface typically using a corrosion-resistant paint.

Independently, of reflective members in automobile lights, extension members and other members requiring graphical design functions should have a reflectance of various luminosities from the viewpoint of design function. A pure chromium (Cr) reflective film (reflectance: about 60%) is used as a metal reflective film having a reflectance lower than that of the pure aluminum reflective film. However, when a reflective film having a reflectance of about 70% is to be prepared, the pure chromium reflective film has an excessively low reflectance, and instead of this, a reflective film having a desired reflectance is prepared typically by coating the surface of a pure aluminum reflective film with a smoke paint for a lower reflectance.

As another possible solution to control the reflectance, pure aluminum is alloyed with one or more other elements so as to have a lower reflectance. However, such an aluminum alloy film should be designed on its composition in consideration of thermal stability, because the aluminum alloy film, when used typically in an automobile light, repeatedly undergoes heating typically by a lamp and subsequent cooling. The aluminum alloy film, if designed on its composition without considering the thermal stability, may suffer from cracks and/or wrinkles when there is a large difference in coefficient of thermal expansion between the aluminum alloy film and a substrate on which the film is deposited (deposition substrate) or when the aluminum alloy film has insufficient ductility.

In contrast, the pure aluminum reflective film, when used typically in an automobile light, suffers from poor productivity regardless of the presence or absence of the reflectance control, because a coating film (e.g., protective film) should be formed on the reflective film, as described above.

For a laser light reflective film use, there is used an aluminum alloy film containing any of transition elements belonging to Group IIIa, Group IVa, Group Va, Group VIa, Group VIIa, and Group VIIIa of the periodic table, which aluminum alloy film has satisfactory corrosion resistance and shows a high reflectance (see Japanese Unexamined Patent Application Publication (JP-A) No. H07-301705). This aluminum alloy film shows excellent corrosion resistance in acidic to neutral regions but cannot be used without a protective film in an alkaline region, because the composition of this film is designed on the concept of forming a chemically stable passive state (passive film), and no consideration is given to the improvement in corrosion resistance in the alkaline region where corrosion proceeds through the dissolution of the passive film. In addition, the aluminum alloy film is not designed on its composition from the viewpoint of thermal stability and is not usable as intact in an automobile light.

Furthermore, the aluminum alloy film, if adopted to a reflective film having a controlled luminosity, is not suitable for this application, because the film is not inherently designed on its composition from the viewpoints of decreasing the reflectance and having satisfactory atomic percent and may thereby suffer from an insufficiently decreased reflectance or may suffer from cracks even when the transition elements are added in the maximum content of 10 atomic percent.

There has been also proposed an aluminum alloy reflective film further containing Mg (Mg content: 0.1 to 15 percent by mass) in addition to Al, to improve corrosion resistance (see JP-A No. 2007-72427). Magnesium (Mg), even when added in a large amount, does not so contribute to the reduction in reflectance and contributes to the improvement in resistance to alkali corrosion to some extent but not significantly. In addition, this aluminum alloy reflective film is not usable as intact in an automobile light, because the film, if exposed to hot and humid surroundings without a protective film, is gradually oxidized and becomes transparent.

JP-A No. 2007-70721 proposes an aluminum alloy reflective film containing Mg in a content of 0.1 to 15 percent by mass and further containing a rare-earth element in a content of 0.1 to 10 percent by mass, which aluminum alloy corresponds to the alloy system disclosed in JP-A No. 2007-72427, except for further containing one or more rare-earth element so as to have improved resistance to hot and humid surroundings. However, even this aluminum alloy reflective film is not usable without a protective film in an automobile light, because its resistance to alkali corrosion is improved little.

The aluminum alloy reflective films disclosed in these literatures, when to be adopted to reflective films having controlled or regulated luminosities, may not have sufficiently regulated luminosities, because Mg element does not so reduce the reflectance of aluminum films. In addition, the aluminum alloy reflective film, even if containing one or more rare-earth elements in a content of 10 percent by mass, which is the upper limit in the claims of the patent literature, does not show a sufficiently decreased reflectance (luminosity) due to the small content of the rare-earth elements and is thereby not suitable for the application.

### CITATION LIST

### Patent Literature

PTL 1: JP-A No. H07-301705

PTL 2: JP-A No. 2007-72427

PTL 3: JP-A No. 2007-70721

### SUMMARY OF INVENTION

### Technical Problem

The present invention has been made under such circumstances, and an object thereof is to provide an aluminum alloy reflective film which has, even when bearing no protective film, excellent alkali resistance (resistance to alkali corrosion), acid resistance (resistance to acid corrosion), and humidity resistance (resistance in hot and humid surroundings) and thereby does not need a protective film. Another object of the present invention is to provide automobile lights, illuminators, and ornamentations each including the aluminum alloy reflective film. Still another object of the present invention is to provide an aluminum alloy sputtering target which can give the aluminum alloy reflective film.

### Solution to Problem

After intensive investigations to achieve the objects, the present inventors have reached the present invention. Specifically, the objects are achieved by the present invention.

The present invention, which has been thus made and achieves the objects, provides an aluminum alloy reflective film, as well as an automobile light, an illuminator, an ornamentation, and an aluminum alloy sputtering target as mentioned below.

(1) An aluminum alloy reflective film containing at least one element selected from the group consisting of Gd, La, Y, Sc, Tb, Lu, Pr, Nd, Pm, Ce, Dy, Ho, Er, and Tm in a content of 2.5 to 20 atomic percent, with the remainder consisting of Al and inevitable impurities.

(2) The aluminum alloy reflective film according to (1), which contains at least one element selected from the group consisting of Sc, Y, La, Gd, Tb, and Lu in a content of 2.5 to 20 atomic percent, with the remainder consisting of Al and inevitable impurities.

(3) The aluminum alloy reflective film according to (2), which contains at least one element selected fmm the group consisting of Sc, Y, La, Gd, ‘lb, and Lu in a content of 2.5 to 6 atomic percent.

(4) The aluminum alloy reflective film according to (2), which contains at least one element selected from the group consisting of Sc, Y, La, Gd, Tb, and Lu in a content of more than 6 atomic percent but 20 atomic percent or less.

(5) The aluminum alloy reflective film according to (3), which contains at least one element selected fmm the group consisting of La, Gd, and Yin a content of 2.5 to 6 atomic percent.

(6) The aluminum alloy reflective film according to (1), which further contains at least one element selected from the group consisting of Cr, Cu, Ag, Ni, Co, Mn, Si, Mo, V, Fe, and Be in a content of 15 atomic percent or less (excluding 0%).

(7) The aluminum alloy reflective film according to (6), which contains at least one element selected from the group consisting of Gd, La, Y, Sc, Tb, Lu, Pr, Nd, Pm, Ce, Dy, Ho, Er, and Tm in a content of 2.5 to 6 atomic percent.

(8) The aluminum alloy reflective film according to (7), which contains Cr in a content of 3.0 atomic percent or less.

(9) The aluminum alloy reflective film according to (7), which contains Cu and/or Ag in a content of 10.0 atomic percent or less.

(10) An automobile light including the aluminum alloy reflective film according to any one of (1) to (9) as a reflective film.

(11) An illuminator including the aluminum alloy reflective film according to any one of (1) to (9) as a reflective film .

(12) An ornamentation including the aluminum alloy reflective film according to any one of (1) to (9) as a reflective film.

(13) An aluminum alloy sputtering target containing at least one element selected from the group consisting of Gd, La, Y, Sc, Tb, Lu, Pr, Nd, Pm, Ce, Dy, Ho, Er, and Tm in a content of 2.5 to 35 atomic percent, with the remainder consisting of Al and inevitable impurities.

(14) The aluminum alloy sputtering target according to (13), which contains at least one element selected from the group consisting of Sc, Y, La, Gd, Tb, and Lu in a content of 2.5 to 35 atomic percent, with the remainder consisting of Al and inevitable impurities.

(15) The sputtering target according to (13), which further contains at least one element selected from the group consisting of Cr, Cu, Ag, Ni, Co, Mn, Si, Mo, V, Fe, and Be in a content of 20 atomic percent or less (excluding 0%).

(16) The sputtering target according to (15), which contains at least one element selected from the group consisting of Gd, La, Y, Sc, Tb, Lu, Pr, Nd, Pm, Ce, Dy, Ho, Er, and Tm in a content of 2.5 to 8 atomic percent.

(17) The aluminum alloy sputtering target according to any one of (13) to (16), which is manufactured through spray forming.

### Advantageous Effects of Invention

The aluminum alloy reflective film according to the present invention excels in alkali resistance (resistance to alkali corrosion), acid resistance (resistance to acid corrosion), and humidity resistance (resistance in hot and humid surroundings) even when bearing no protective film, and thereby does not need a protective film. The aluminum alloy reflective film is therefore advantageously usable as a reflective film without requiring a protective film and, in this use, the resulting reflective film can be manufactured without deterioration in productivity due to the formation of the protective film, and the reflective film itself shows higher durability, thus being useful.

The aluminum alloy sputtering target according to the present invention enables the formation of the aluminum alloy reflective film according to the present invention.

The automobile light, illuminator, and ornamentation according to the present invention each include the aluminum alloy reflective film according to the present invention as a reflective film and thereby do not need a protective film. They are advantageously usable without requiring a protective film and, in their uses, do not suffer from deterioration in productivity due to the formation of the protective film, and they themselves show higher durability, thus being useful.

### BRIEF DESCRIPTION OF DRAWINGS

FIG. 1 is a diagram illustrating Auger electron spectroscopic data of a specimen according to an example (Example 1-7) before an alkali resistance test.

FIG. 2 is a diagram illustrating Auger electron spectroscopic data of the specimen according to the example (Example 1-7) after the alkali resistance test.

FIG. 3 is a diagram illustrating Auger electron spectroscopic data of a specimen according to an example (Example 1-10) before the alkali resistance test.

FIG. 4 is a diagram illustrating Auger electron spectroscopic data of the specimen according to the example (Example 1-10) after the alkali resistance test.

FIG. 5 is a diagram illustrating Auger electron spectroscopic data of a specimen according to a comparative example (Comparative Example 1-6) before the alkali resistance test.

FIG. 6 is a diagram illustrating Auger electron spectroscopic data of the specimen according to the comparative example (Comparative Example 1-6) after the alkali resistance test.

### DESCRIPTION OF EMBODIMENTS

The aluminum alloy reflective film according to the present invention contains at least one element selected from the group consisting of Gd, La, Y, Sc, Tb, Lu, Pr, Nd, Pm, Ce, Dy, Ho, Er, and Tm (Group A) in a total content of 2.5 to 20 atomic percent, with the remainder consisting of Al and inevitable impurities. As used herein the “content” refers to a content of a single element when the aluminum alloy reflective film contains one element selected from Group A, and refers to a total content when the aluminum alloy reflective film contains two or more elements selected from Group A The definition of the “content” is also adopted to other groups of elements in the similar mariner hereinafter. The Al-(Group A) alloy film containing at least one element of Group A serves as a reflective film which maintains a high reflectance over a long period of time and excels in properties such as alkali resistance, acid resistance, and thermal stability even when bearing no protective film. As used herein the term “alkali resistance” refers to a property being not corroded and being resistant to deterioration in reflectance even in an alkaline environment. Also as used herein the term “acid resistance” refers to a property being not corroded and being resistant to deterioration in reflectance even in an acidic environment. The term “humidity resistance” refers to resistance in hot and humid surroundings and refers to a property being not corroded and being resistant to deterioration in reflectance even in such surroundings.

Of Group A elements, at least one of Sc, Y, La, Gd, Tb, and Lu (hereinafter also referred to as “Sc to Lu”) is preferred for further improving properties such as alkali resistance, acid resistance, and thermal stability.

An aluminum alloy film containing one or more rare-earth elements (hereinafter also referred to as “REM(s)) as added to aluminum in a content of 2.5 atomic percent or more shows a reflectance lower than the theoretical reflectance of pure aluminum (88%), but ensures sufficiently excellent humidity resistance and shows further higher acid resistance and further higher alkali resistance. This film is therefore adoptable as a reflective film without deterioration even when bearing no protective film.

When Al is alloyed with a REM, the resulting alloy does not suffer from significant decrease in humidity resistance and thereby ensures sufficiently excellent humidity resistance. In an acidic environment, the alloy shows a less noble immersion potential than that of the pure aluminum, and this prevents Al from dissolving and retards the dissolution rate of Al. In a basic environment, the aluminum alloy containing a REM (hereinafter also referred to as “Al-REM alloy) shows a less noble immersion potential due to the presence of the REM and has a lower dissolution rate, because the REM precipitates and concentrates as a hydroxide at the surface of the Al-REM alloy during dissolution to form a protective film. However, of REMs, Eu, Sm, and Yb show less effects for retarding the dissolution rate, because these elements, when immersed in an alkali (base), become ions, thereby dissolve in the alkaline solution, and fail to precipitate at the surface of the Al-REM alloy. For this reason, REMs effective for reducing or retarding the dissolution rate are REMs belonging to Group A, of which “Sc to Lu” are preferred. The elements belonging to “Sc to Lu” are less coloring even when precipitated at the surface of the Al-REM alloy and suffer from less discoloration even after the immersion in an alkali. In contrast, Ce and other REMs than the “Sc to Lu” cause discoloration when they concentrate at the surface of the Al-REM alloy, because ions of these elements (rare-earth element ions) each have a color such as yellow or brown. Such discoloration impairs the appearance of the reflective film, thus being undesirable.

Among them, Y, La, Gd, Tb, and Lu are preferred, of which La, Gd, and Y are more preferred as elements to be alloyed with Al, in consideration of the corrosion resistance of the film and the production cost of the sputtering target for use in the deposition

The content of “Sc to Lu” is preferably 2.5 to 20 atomic percent. The elements “Sc to Lu”, if in a content of less than 2.5 atomic percent, may not sufficiently lower the alkali dissolution rate, and this may cause the dissolution of Al and cause a lower reflectance when the reflective film is used without a protective film. The content of “Sc to Lu” is more preferably 3.0 atomic percent or more. In contrast, the “Sc to Lu”, if present in a content of more than 20 atomic percent, may cause insufficient thermal stability under heating/cooling conditions and may cause wrinkles of the aluminum alloy film containing “Sc to Lu” during the heating/cooling process. The wrinkling (generation of wrinkles) is probably caused by the plastic deformation of the film during heating, indicating that the presence of “Sc to Lu” may not cause the film to have a lower ductility.

Based on these, preferred is an aluminum alloy reflective film containing at least one of “Sc to Lu” in a total content of 2.5 to 20 atomic percent, with the remainder consisting of Al and inevitable impurities. As is demonstrated above, such an aluminum alloy reflective film according to the present invention excels in alkali resistance, acid resistance, and humidity resistance even when bearing no protective film, and this negates the need for protective film. The aluminum alloy reflective film mentioned above does not suffer typically from wrinkling during the heating/cooling process, shows no problem in thermal stability under heating/cooling conditions, and has sufficient thermal stability. Accordingly, it can be said that the aluminum alloy reflective film according to the present invention can have such excellent alkali resistance, acid resistance, and humidity resistance while ensuring the sufficient thermal stability, and this eliminates the need for protective film. The unnecessity of protective film protects the film from having lower productivity due to the formation of the protective film.

When the film contains Al added with one or more REMs in a content of 2.5 to 6 atomic percent, the film shows a reflectance lower than the theoretical reflectance (88%) of pure aluminum but ensures a high reflectance of 84% or more and less than 88%. For this reason, the aluminum alloy reflective film according to the present invention, in a preferred embodiment of containing at least one of “Sc to Lu” in a specific content of from 2.5 to 6 atomic percent, can ensure a high reflectance of 84% or more and less than 88%. The aluminum alloy reflective film according to this embodiment ensures the sufficient thermal stability, excels in alkali resistance, acid resistance, and humidity resistance as mentioned above, thus requires no protective film, and surely has a high reflectance of 84% or more and less than 88%.

An aluminum alloy film having a reflectance of less than 84% can be obtained by adding to Al at least one of “Sc to Lu” in a content of more than 6 atomic percent. An aluminum alloy film having such a low reflectance can also be obtained by adding one or more elements other than “Sc to Lu”. In this case, however, the aluminum alloy film may become hardened due to solid-solution strengthening or precipitation strengthening, may thereby show insufficient thermal stability under heating/cooling conditions, and may suffer from cracking during the heating/cooling process. In contrast, the addition of “Sc to Lu” does not cause such cracking. However, “Sc to Lu”, if present in an excessively large content (more than 20 atomic percent), may cause the aluminum alloy film to suffer from wrinkling. The aluminum alloy film, when containing at least one of “Sc to Lu” in a content of 20 atomic percent or less, does not suffer from the wrinkling, maintains excellent thermal stability, and has a reflectance reduced to about 70%. Accordingly, in another preferred embodiment, the aluminum alloy reflective film has a specific content of “Sc to Lu” of more than 6 atomic percent but 20 atomic percent or less and may thereby have a low reflectance of less than 84% but about 70% or more. The aluminum alloy reflective film according to this embodiment ensures sufficient thermal stability as above, simultaneously shows the excellent alkali resistance, acid resistance, and humidity resistance, thereby requires no protective film, and has a low reflectance of less than 84% but about 70% or more. When the film can have a low reflectance of less than 84% but about 70% or more, the film does not need the coating of a smoke paint to obtain such a low reflectance, and this protects the film from having lower productivity due to the coating typically of the smoke paint.

Some of the aluminum alloy reflective films may show poor warm-water resistance, and, when subjected to a warm-water resistance test (warm water immersion test) simulating a dewing environment, may become transparent, may show a remarkably lowered reflectance, or may suffer from countless pinholes in the early stages of immersion. Though details of reasons remain unknown, such films become transparent probably mainly because Al dissolves out preferentially in a portion where a natural oxide film of aluminum (working as a protective film) is fragile or thin, and the dissolved aluminum is oxidized to form a hydroxide film, and through this, oxygen enters the film to proceed the oxidation of the Al (alloy) film. To avoid this and to have higher water resistance (waterproofness), the aluminum alloy film may contain at least one of Group A, preferably in a content of 2.5 to 6 atomic percent, in combination with at least one element selected from the group consisting of Cr, Cu, Ag, Ni, Co, Mn, Si, Mo, V, Fe, and Be (Group B) in a content of 15 atomic percent or less (excluding 0%), with the remainder consisting of Al and inevitable impurities.

The elements of Group B effectively exhibit the activity of improving the warm-water resistance even in a small content. Specifically, the content of elements of Group B in the aluminum alloy reflective film is preferably about 0.1 atomic percent or more, more preferably 0.3 atomic percent or more, and furthermore preferably 0.5 atomic percent or more. From the viewpoint of improving the warm-water resistance, the higher the content of elements of Group B is, the better. However, elements of Group B, if present in an excessively high content, may cause the film to have a low reflectance (less than 70%) immediately after deposition, and, to avoid this, the upper limit of the content is herein specified to be 15 atomic percent or less. The content of Group B elements is preferably 12 atomic percent or less, more preferably 10 atomic percent or less, furthermore preferably 7.0 atomic percent or less, and still more preferably 5.0 atomic percent or less.

Technically, the upper limit of the preferred content of Group B element(s) varies depending on the type of the Group B element(s) to be added. For example, when Cr is used as a Group B element, the Cr content is preferably controlled to be 3.0 atomic percent or less, more preferably 2.0 atomic percent or less, and furthermore preferably 1.5 atomic percent or less. The aluminum alloy reflective film, if having a Cr content of more than 3.0 atomic percent, may have a remarkably low reflectance immediately after deposition To avoid this and to balance between the reflectance immediately after deposition and the warm-water resistance, the Cr content is preferably about 3 atomic percent or less.

When Ag and/or Cu is used as a Group B element, the content of these elements is preferably controlled to be 10.0 atomic percent or less, more preferably 7 atomic percent or less, furthermore preferably 5 atomic percent or less, and still more preferably 3 atomic percent or less. The content herein refers to a content of a single element when the film contains either one of Ag and Cu, and the content refers to a total content of Ag and Cu when the film contains both Ag and Cu. In general, Ag and Cu tend to lower the reflectance immediately after deposition less effectively than Cr as mentioned above, but these elements, if present in a content of more than 10.0 atomic percent, may cause the aluminum alloy reflective film to have a remarkably low reflectance immediately after deposition. Technically, when the aluminum alloy film contains Ag without Cu, Ag may be added in a content of up to 11.0% as described in working examples mentioned later.

The aluminum alloy reflective film according to the present invention has a high reflectance and is advantageously usable typically in automobile lights, illuminators, or ornamentations. The aluminum alloy reflective film according to the present invention has been verified to exhibit satisfactory alkali resistance and acid resistance even when bearing no protective film. The automobile lights and other resulting articles using the aluminum alloy reflective film according to the present invention not only endure a long-term use (has excellent durability) but also are prevented from increasing in production cost.

The aluminum alloy reflective film according to the present invention is preferably formed through sputtering to a substrate using an aluminum alloy target. This is because the sputtering technique easily gives a thin film which more excels in in-plane uniformity of composition and film thickness than thin films formed through other techniques such as ion plating, electron beam deposition, and vacuum deposition. The aluminum alloy reflective film is particularly preferably formed through a direct-current (DC) sputtering technique using a direct-current (DC) power source/cathode. A material for the substrate is not limited, as long as being one generally used in automobile lights and illuminators each including an aluminum alloy reflective film, and examples thereof include resins and glass. Exemplary resins include polycarbonate resins, acrylic resins, polyester resins (e.g., PETs (poly(ethylene terephthalate)s) and PBTs (poly(butylene terephthalate)s), ABS resins, epoxy resins, acetal resins, and alicyclic hydrocarbon resins; as well as mixtures of these resins.

It should be noted, however, an aluminum alloy sputtering target having a different composition from the desired composition of the aluminum alloy reflective film is to be prepared in consideration of yield. Though the detailed mechanism remains unknown, there is a difference in composition between the sputtering target and the resulting film probably because a rare-earth element which has been once taken into the film is re-sputtered by the action of newly sputtered incident particles. Typically, among Gd, Y, and La, the yield decreases in the order of Y>Gd>La, and this order agrees with the order of atomic radius (Y>Gd>La). This is probably because an element having a larger atomic radius has a larger area and is re-sputtered with a higher probability. In the experimental examples mentioned later, the yield decreases in the order of Gd>Y>La, but the yield of a sputtering target containing Y varies little depending on the content of Y, whereas the yields of sputtering targets containing Gd and La, respectively, vary depending on the contents of Gd and La. Accordingly, among these elements, Y shows a highest yield at a high element content. As used herein the term “yield” refers to a value determined according to the formula: Yield=[(Concentration of element in aluminum alloy reflective film)/(Concentration of element in aluminum alloy sputtering target)]×100 (%).

In consideration of the yield, a sputtering target for use herein is preferably an aluminum alloy sputtering target containing at least one Group A element (or at least one of “Sc to Lu”) in a content of 2.5 to 35 atomic percent, with the remainder consisting of Al and inevitable impurities; or a sputtering target containing at least one Group A element in a content of 2.5 to 8 atomic percent; and at least one Group B element in a content of 20 atomic percent or less (excluding 0%), with the remainder consisting of Al and inevitable impurities. The shape of the aluminum alloy sputtering target is not limited and may be any arbitrary shape (e.g., rectangular plate shape, circular plate shape, or toroidal plate shape) processed according to the shape and structure of the sputtering apparatus.

The aluminum alloy sputtering target may be manufactured by any method not limited, but is preferably manufactured by a method using spray forming. This is because the aluminum alloy sputtering target mani ifactured by spray forming may be highly uniform in composition and structure and can give an aluminum alloy reflective film being uniform in composition and structure.

### EXAMPLES

Some working examples according to the present invention and comparative examples thereto will be illustrated below. It should be noted, however, that these examples are never intended to limit the scope of the present invention; various alternations and modifications may be made without departing from the scope and spirit of the present invention and all fall within the scope of the present invention

### Experimental Examlpe 1 (Example 1 and Comparative Example 1)

Aluminum alloy films having the compositions given in Table 1 were each deposited on a glass substrate (Corning #1737) using a DC magnetron sputtering apparatus. A way to carry out the deposition will be illustrated in detail below.

Composite sputtering targets each composed of a pure aluminum sputtering target having a diameter of 101.6 mm and bearing thereon one or more chips of a desired metal element (metal element to be added) were prepared as sputtering targets for deposing the aluminum alloy films and were each attached to an electrode in a chamber of the sputtering apparatus, followed by evacuation to a pressure in the chamber of 1.3×10³ Pa or less. To deposit a pure aluminum film, a pure aluminum sputtering target was used as a sputtering target.

Next, Ar gas was fed into the chamber, and the pressure in the chamber was controlled to 2.6×10⁻¹ Pa. Sputtering was then performed while applying a power of 260 W to the sputtering target from a direct-current (DC) power source to carry out deposition of an aluminum alloy film having a desired composition on an entire surface of the substrate. Thus, a series of specimens was obtained.

In this process, the aluminum alloy films were controlled to have different compositions by changing the type of metal element and number of the chips to be arranged on the pure aluminum sputtering target, whereas the film thickness was controlled to be 150 nm by regulating the deposition time.

The specimens prepared according to the deposition process were each subjected to a compositional analysis, reflectance measurement, alkali resistance test, acid resistance test, and humidity resistance test. These measurements and tests were performed according to the following methods.

### <Compositional Analysis>

The composition of each specimen aluminum alloy film was measured through inductively coupled plasma (ICP) emission spectrometry. Specifically, the specimen was dissolved in such an acid as to dissolve the aluminum alloy film to give a solution, and the ratio between Al and an added element in the solution was measured through ICP emission spectrometry, and the measured ratio was standardized to 100% and defined as the composition of the aluminum alloy film.

### <Measurement of Visible Light Reflectance>

The reflectance of each specimen deposited on the glass substrate was measured at wavelengths of from 250 nm to 800 nm, and based on this, a visible light reflectance was calculated in accordance with Japanese Industrial Standards (JIS) 3106.

### <Alkali Resistance Test>

Each specimen deposited on the glass substrate was subjected to an alkali resistance test. Specifically, a predetermined area of the aluminum alloy film was masked, and the masked portion (masked area) and a portion not masked (exposed area) were together immersed in a 1 percent by weight KOH aqueous solution for a duration of up to 5 minutes, rinsed with water, and dried, followed by the removal of masking. When the aluminum alloy film dissolved, and through which the glass substrate was seen within a time shorter than 5 minutes, the immersion was completed at that point.

After the removal of masking, a level difference between the masked area and the exposed area was measured with a surface profiler (Dektak 6M), and this was defined as a dissolved quantity (nm). A dissolution rate (nm/sec) was then calculated from the immersion time (sec) and the dissolved quantity (nm). Specifically, the dissolution rate was determined according to the formula: (Dissolved quantity)/(Immersion time)=Dissolution rate. A specimen having a dissolution rate of one half or less of that of the pure aluminum film was evaluated as accepted (∘).

After the test, the visible light reflectance of the specimen was measured by the procedure of the visible light reflectance measurement, to calculate a chromaticity. In this test, a specimen having a chromaticity b* of less than 3 points was evaluated as accepted (∘), because a specimen having a chromaticity b* (b-star) of 3 points or more would look yellow.

### <Acid Resistance Test>

Each specimen deposited on the glass substrate was subjected to an acid resistance test. Specifically, a predetermined area of the aluminum alloy film was masked, and the masked portion (masked area) and a portion not masked (exposed area) were together immersed in a 1 percent by weight H₂SO₄ aqueous solution for a duration of up to 5 minutes, rinsed with water, and dried, followed by the removal of masking. After the removal of masking, a level difference between the masked area and the exposed area was measured with a surface profiler (Dektak 6M), and this was defined as a dissolved quantity (nm). A dissolution rate (nm/sec) was then calculated from the immersion time (sec) and the dissolved quantity (nm). Specifically, the dissolution rate was determined according to the formula: (Dissolved quantity)/(Immersion time)=Dissolution rate. After the test, the visible light reflectance of the specimen was measured by the procedure of the visible light reflectance measurement to calculate a chromaticity. In this test, a specimen having a chromaticity b* of less than 3 points was evaluated as accepted.

### <Humidity Resistance Test>

Each specimen deposited on the glass substrate was subjected to a humidity resistance test. Specifically, the specimen was held for 240 hours in a furnace which was held at a temperature of 55° C. and relative humidity of 95% and then retrieved from the furnace. Subsequently, the visible light reflectance of the specimen was measured and calculated by the procedure of the visible light reflectance measurement. A specimen having a change in visible light reflectance between before and after the humidity resistance test of 1% or less was evaluated as accepted (∘).

The results of the measurements and tests are shown in Table 1. Specifically, Table 1 illustrates, of each specimen aluminum alloy film, the composition, the visible light reflectance, the alkali resistance test results (dissolution rate obtained by the alkali resistance test, and chromaticity b*), and the humidity resistance test results.

With reference to Table 1, Examples 1-1 to 1-12 and Comparative Example 1-4 (this sample is a working example according to the present invention, but is indicated as a “comparative example” in the relationship to the invention as claimed in claim 3) are examples (working examples) according to the present invention. They each had a dissolution rate in the alkali resistance test of one half or less of that of the pure aluminum film, were evaluated as accepted (∘), and were found to have good alkali resistance (accepted). In the humidity resistance test, they each showed a change in visible light reflectance between before and after the test of 1% or less, were thereby evaluated as accepted (∘), and were found to have good humidity resistance (accepted). In addition, they had very satisfactory acid resistance, because they showed no detectable level difference between the masked area and the exposed area after the acid resistance test, showed such a small dissolution rate (dissolved very little), and had a very small chromaticity b* of 1 point or less (not shown in Table 1).

In contrast, Comparative Examples 1-1, 1-2, and 1-3, and Comparative Example 1-5 are comparative examples to the examples according to the present invention. In the alkali resistance test, they each showed a dissolution rate of more than one half of that of the pure aluminum film, to be evaluated as rejected (×) and/or had a chromaticity b* of 3 points or more to be evaluated as rejected (×), and were found to have poor alkali resistance (rejected). Of these, Comparative Example 1-2 was also found to have poor humidity resistance (rejected), because it showed a change in visible light reflectance between before and after the humidity resistance test of more than 1% and was evaluated as rejected (×). Regarding the acid resistance, these samples (comparative examples), excluding some samples, each generally had a chromaticity b* larger than those of Examples 1-1 to 1-12 (not shown in Table 1).

It can also be said that, of the samples, Examples 1-1 to 1-12 are working examples according to the invention of claim 3, whereas Comparative Examples 1-1 to 1-5 are comparative examples to the examples according to the invention of claim 3. Hereinafter Examples 1-1 to 1-12 will be treated as working examples according to the invention of claim 3, and Comparative Examples 1-1 to 1-5 will be treated as comparative examples to the working examples according to the invention of claim 3. These comparative examples and working examples according to the invention of claim 3 will be described below.

As is demonstrated by Table 1, Comparative Example 1-1 is a pure aluminum film, had a reflectance lower than the theoretical reflectance (88%) because the film deposited by sputtering had a rough surface. In addition, this sample showed a large dissolution rate in the alkali resistance test and was found to have poor alkali resistance (rejected). Comparative Example 1-2 is an Al—Mg alloy film, had a reflectance of 88% or more even at a high Mg content of more than 6 atomic percent, because Mg, even present in a high content, does not act to lower the reflectance of Al. However, this sample showed a large dissolution rate in the alkali resistance test and was found to have poor alkali resistance (rejected), because Mg does not so effectively improve the alkali resistance. In addition, the sample film was oxidized and thereby became transparent in the humidity resistance test, thereby showed a significantly lowered reflectance, and was found to have remarkably poor humidity resistance (rejected). Comparative Example 1-3 is an Al—Ce alloy film, had a chromaticity b* of 3 points or more after the alkali test because of coloring of Ce concentrated at the film surface after the test, showed a poor appearance as a reflective film, and was found to have poor alkali resistance (rejected). Comparative Example 1-4 (this sample is a working example according to the present invention, but is indicated as a “comparative example” in the relationship to the invention of claim 3) is an Al—La alloy film, but had a La content larger than the specific alloy element content (2.5 to 6 atomic percent) as specified in the invention of claim 3, and thereby had a low initial reflectance of less than 84%. Comparative Example 1-5 is an Al—Eu alloy film, contained no element which improves the alkali resistance, showed a large dissolution rate in the alkali resistance test, and was found to have poor alkali resistance (rejected).

Examples 1-1 to 1-12 as working examples according to the invention of claim 3 each had a high reflectance in terms of initial reflectance of 84% or more and less than 88%, and were found to have good alkali resistance (accepted) in the alkali resistance test, becai i se they showed a small dissolution rate of one half or less of that of the pure aluminum film to be evaluated as accepted (∘) and had a chromaticity b* of less than 3 points to be evaluated as accepted (∘). They each had a change in visible light reflectance between before and after the humidity resistance test of 1% or less, were evaluated as accepted (∘), and were found to have good humidity resistance (accepted). As has been described above, these samples also showed such a small dissolution rate that the level difference between the masked area and the exposed area after the acid resistance test was not detected, also had a very small chromaticity b* of 1 point or less, and were thereby found to have very good acid resistance (not shown in the table). Specifically, Examples 1-1 to 1-12 as working examples according to the invention of claim 3 each had an initial reflectance of 84% or more and less than 88% and had excellent alkali resistance, acid resistance, and humidity resistance as mentioned above, even though bearing no protective film.

Independently, each of the specimens before and after the alkali resistance test was subjected to an Auger electron spectroscopy (AES) to determine how concentrations of elements distribute in the depth direction. The AES analysis herein was performed on a region with a diameter of 10 μm using the PHI 650 scanning Auger electron spectrometer supplied by Perkin-Elmer. A depth determined by AES was a converted value using the rate in the case where SiO₂ is sputtered.

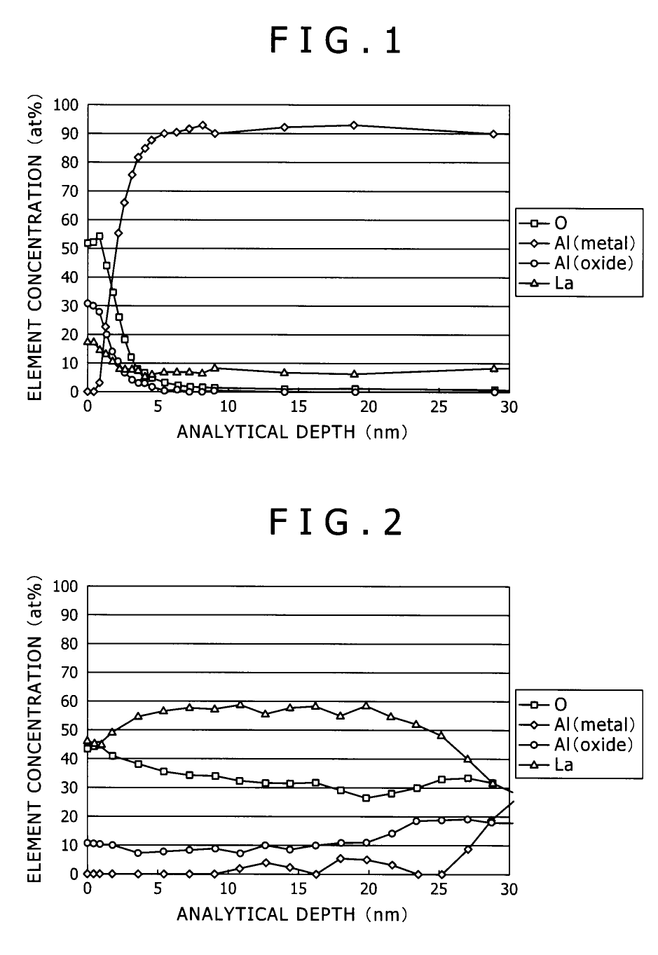

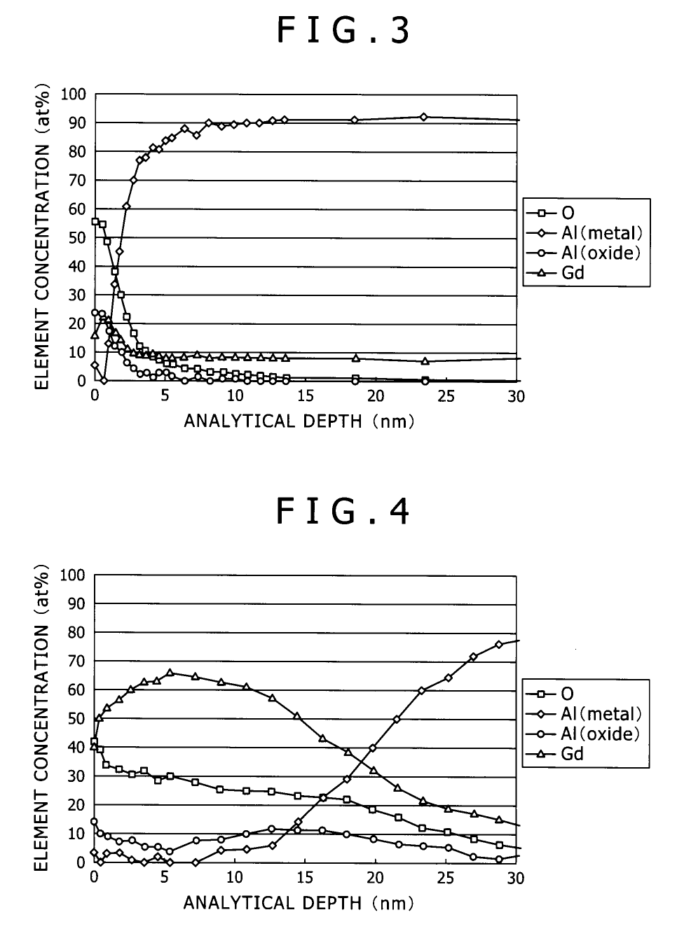

The results of AES analyses on the specimens according to Examples 1-7 and 1-10 are shown in FIGS. 1 to 4. The data indicate that specimens before the alkali resistance test include an oxide film containing Al and La (FIG. 1) or Al and Gd (FIG. 3) in a region from the surface to a depth of several nanometers and include an alloy of Al—La or Al—Gd being present inside of the oxide film. The data also demonstrate that the surface of the film after the alkali resistance had an Al concentration lower than that before the alkali resistance test and had a concentration of La or Gd of higher than that before the alkali resistance test (FIGS. 2 and 4).

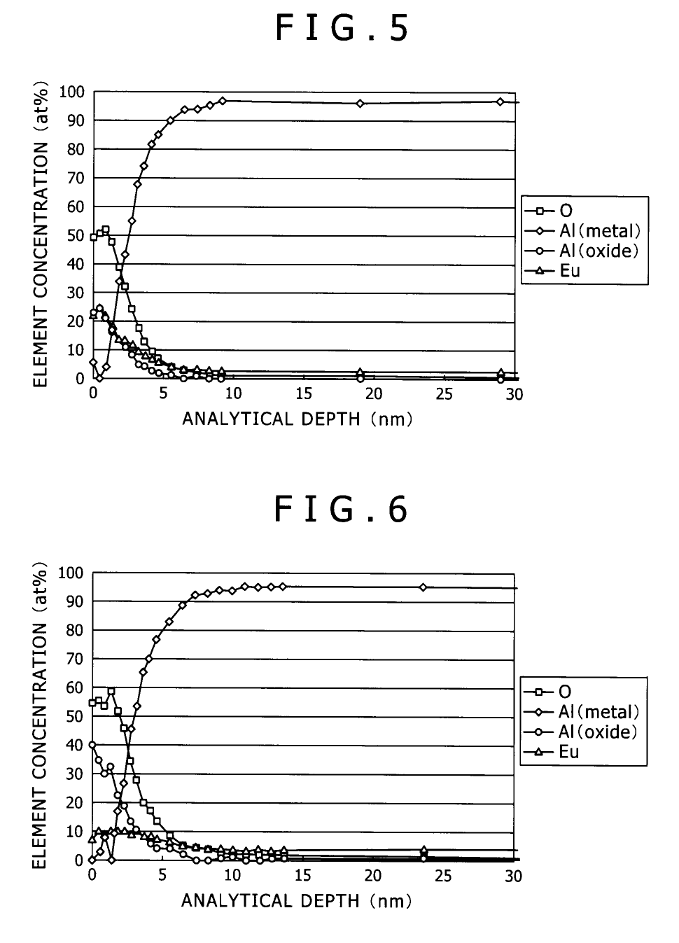

The results of AES analyses on the specimen according to Comparative Example 1-5 are shown in FIGS. 5 and 6. The data indicate that the specimen before the alkali resistance test include an oxide film containing Al and Eu (FIG. 5) in a region fium the surface to a depth of several nanometers and includes an alloy of Al—Eu being present inside of the oxide film. The data also demonstrate that the surface of the film after the alkali resistance test had an Eu concentration lower than that before the alkali resistance test; and that Eu does not concentrate at the surface after the alkali resistance test, unlike La and Gd (FIG. 6).

### Experimental Example 2 (Example 2 and Comparative Example 2)

Aluminum alloy thin films having the compositions given in Table 2 were each deposited on a glass substrate (Corning #1737) by the procedure of Experimental Example 1. For heat-crack resistance test specimens, aluminum alloy thin films were each deposited on a PET/PBT resin substrate (coefficient of thermal expansion: 5×10⁻⁵/°C.

Specimens obtained through the deposition were each subjected to a compositional analysis, reflectance measurement, alkali resistance test, thermal stability test, acid resistance test, and humidity resistance test. The compositional analysis, reflectance measurement, alkali resistance test, acid resistance test, and humidity resistance test were performed by the methods as in Experimental Example 1. As the thermal stability test, a heat-crack resistance test was performed according to the following method.

### <Heat-Crack Resistance Test>

Each of the specimens deposited on the PET/PBT resin substrate was subjected to the heat-crack resistance test. Specifically, the specimen was kept in an atmospheric heat-treatment furnace heated to 160° C. for 1 hour and then cooled to room temperature in the furnace. The surface of the specimen was then observed with an optical microscope or scanning electron microscope to detect whether cracks and wrinkles were generated. A specimen indicating neither cracking nor wrinkling was evaluated as accepted, whereas a sample indicating cracking or wrinkling was evaluated as rejected.

The results of the measurements and tests are shown in Table 2. Specifically, Table 2 illustrates, of each specimen aluminum alloy film, the composition, the visible light reflectance, alkali resistance test results (dissolution rate obtained by the alkali resistance test, and chromaticity b*), the heat-crack resistance test results, and the humidity resistance test results.

With reference to Table 2, Examples 2-1 to 2-4 are working examples according to the present invention. In the alkali resistance test, these samples each had a dissolution rate of one half or less of that of the pure aluminum film to be evaluated as accepted (∘), had a chromaticity b* of less than 3 points to be evaluated as accepted (∘), and were found to have good alkali resistance (accepted). In the humidity resistance test, they each showed a change in visible light reflectance before and after the test of 1% or less to be evaluated as accepted (∘) and were found to have good humidity resistance (accepted). In addition, they had very good acid resistance, because, after the acid resistance test, they showed no level difference between the masked area and the exposed area, showed such a small dissolution rate (dissolved very little), and had a very small chromaticity b* of 1 point or less (not shown in Table 2).

In contrast, Comparative Examples 2-1 to 2-5 are comparative examples to the examples according to the present invention. In the alkali resistance test, they each had a dissolution rate of more than one half of that of the pure aluminum film, to be evaluated as rejected (×) and/or had a chromaticity b* of 3 points or more to be evaluated as rejected (×), and were thereby found to have poor alkali resistance (rejected). Of these, Comparative Example 2-1 was also found to have poor humidity resistance (rejected), because it showed a change in visible light reflectance between before and after the humidity resistance test of more than 1% and was evaluated as rejected (×). Regarding the acid resistance, these samples (comparative examples), excluding some samples, each generally had a chromaticity b* larger than those of Examples 2-1 to 2-4 (not shown in Table 2).

It can be said that Examples 2-1 to 2-4 are working examples according to the invention of claim 4, whereas Comparative Examples 2-1 to 2-5 are comparative examples to the examples according to the invention of claim 4. Hereinafter Examples 2-1 to 2-4 will be treated as working examples according to the invention of claim 4, and Comparative Examples 2-1 to 2-5 will be treated as comparative examples to the working examples according to the invention of claim 4. These comparative examples and working examples according to the invention of claim 4 will be described below.

As is demonstrated by Table 2, Comparative Example 2-1 is an Al—Mg alloy film, had a not so high reflectance even at a high Mg content, showed a large dissolution rate in the alkali resistance test and was found to have poor alkali resistance (rejected). In addition, this sample had a significantly lowered reflectance after the humidity resistance test and was found to have significantly poor humidity resistance (rejected). Comparative Example 2-2 is an Al—La alloy film, but had a La content of larger than the specific alloy element content (2.5 to 20 atomic percent) as specified in the present invention, thereby was broken (suffered from film breaking) after the heat-crack resistance test, and was evaluated as rejected in heat-crack resistance. Comparative Example 2-3 is an Al—Ce alloy film. After the alkali (resistance) test, this sample was colored to have a chromaticity b* of 3 points or more, showed a poor appearance as a reflective film, and was found to have poor alkali resistance (rejected). Comparative Example 2-4 is an Al—Eu alloy film, in which Eu element is not effective for improving the alkali resistance even present in a content within the specific alloy element content (2.5 to 20 atomic percent) as specified in the present invention. This sample therefore showed a large dissolution rate in the alkali resistance test and was found to have poor alkali resistance (rejected). Comparative Example 2-5 is an Al—Ta alloy film, showed a large dissolution rate in the alkali resistance test, was thereby found to have poor alkali resistance (rejected) and suffered from cracks (cracking) in the heat-crack resistance test and was found to have poor heat-crack resistance (rejected).

Examples 2-1 to 2-4 as working examples according to the invention of claim 4 each had a low reflectance controllable to less than 84% but about 70% or more, and, in the alkali resistance test, they showed an accepted (∘) dissolution rate of one half or less of that of the pure aluminum film, had an accepted (∘) chromaticity b* of less than 3 points, and were found to have good alkali resistance (accepted). In the humidity resistance test, they showed a change in visible light reflectance of 1% or less between before and after the test, to be evaluated as accepted (∘), and were found to have good humidity resistance (accepted). These samples also did not suffer from cracking and wrinkling in the heat-crack resistance test and were found to have acceptable heat-crack resistance. In addition, they had very satisfactory acid resistance, because they showed no detectable level difference between the masked area and the exposed area after the acid resistance test, showed such a small dissolution rate (dissolved very little), and had a very small chromaticity b* of 1 or less (not shown in Table 2). Specifically, Examples 2-1 to 2-4 as working examples according to the invention of claim 4 may have a low initial reflectance of less than 84% but about 70% or more, may have such excellent alkali resistance, acid resistance, and humidity resistance as mentioned above even when bearing no protective film, and may have excellent heat-crack resistance as above to show good thermal stability.

### Experimental Example 3 (Example 3)

Aluminum alloy targets were prepared by adding any of elements Gd, Y, and La to pure aluminum so as to have the target compositions given in Table 3, and making ingots from the resulting materials. Using these targets, thin films were deposited under the deposition conditions of Experimental Example 1.

The resulting specimens obtained by the deposition were each subjected to a compositional analysis, reflectance measurement, alkali resistance test, and humidity resistance test. The compositional analysis, reflectance measurement, alkali resistance test, and humidity resistance test were performed by the methods as in Experimental Example 1.

The results of measurements and tests (evaluations) are shown in Table 3. Table 3 demonstrates that the contents of respective elements of Gd, Y, and La in the thin films in terms of yields were about 70% to 90% with respect to the element contents in the targets, indicating that targets should be prepared in consideration of yields which are corresponding to the apparatus and deposition conditions, in order to allow thin films to have target element contents.

TABLE 1

| | Rare-earth content | | | | Humidity resistance | |
|---|---|---|---|---|---|---|
| | (atomic percent) or | | Alkali resistance test | | test | |
| Film | Mg content (atomic | | Dissolution rate | | Reflectance after test | |
| composition | percent) | Initial reflectance (%) | (nm/sec) | b* after test (points) | (%) | |
| Al—Sc | 3.0 | 87.1 | 0.22 | 2.15 | 87.0 | Example 1-1 |
| Al—Y | 3.2 | 86.9 | 0.18 | 2.23 | 86.5 | Example 1-2 |
| Al—Y | 4.1 | 86.4 | 0.13 | 2.89 | 85.6 | Example 1-3 |
| Al—Y | 5.5 | 84.6 | 0.12 | 2.92 | 84.5 | Example 1-4 |
| Al—La | 2.5 | 87.6 | 0.20 | 2.10 | 87.1 | Example 1-5 |
| Al—La | 4.2 | 85.2 | 0.10 | 1.93 | 85.1 | Example 1-6 |
| Al—La | 5.5 | 84.6 | 0.09 | 2.92 | 84.4 | Example 1-7 |
| Al—Gd | 2.4 | 87.7 | 0.22 | 1.87 | 87.7 | Example 1-8 |
| Al—Gd | 4.1 | 85.3 | 0.07 | 2.65 | 84.3 | Example 1-9 |
| Al—Gd | 5.1 | 85.0 | 0.07 | 2.82 | 84.9 | Example 1-10 |
| Al—Tb | 4.4 | 85.7 | 0.15 | 2.64 | 85.5 | Example 1-11 |
| Al—Lu | 4.2 | 85.9 | 0.17 | 2.58 | 84.5 | Example 1-12 |
| Al | — | 83.8 | 0.46 | 0.42 | 88.8 | Com. Ex. 1-1 |
| Al—Mg | 6.5 | 88.7 | 0.30 | 0.46 | 16.1 | Com. Ex. 1-2 |
| Al—Ce | 3.8 | 84.9 | 0.15 | 8.84 | 84.7 | Com. Ex. 1-3 |
| Al—La | 8.2 | 81.9 | 0.05 | 2.77 | 81.7 | Com. Ex. 1-4 |
| Al—Eu | 2.9 | 87.4 | 0.43 | 1.37 | 87.1 | Com. Ex. 1-5 |

TABLE 2

| | Rare-earth | | | | Heat-crack | | |
|---|---|---|---|---|---|---|---|
| | content (atomic | | | | resistance test | Humidity | |
| | percent) or Mg | | Alkali resistance test | | Presence or | resistance test | |
| Film | content (atomic | Initial reflectance | Dissolution rate | b* after test | absence of | Reflectance after | |
| composition | percent) | (%) | (nm/sec) | (points) | cracking | test (%) | |
| Al—Sc | 13.1 | 77.9 | 0.05 | 2.88 | no cracking | 77.5 | Example 2-1 |
| Al—Y | 8.1 | 82.1 | 0.07 | 2.87 | | 81.7 | Example 2-2 |
| Al—La | 18.1 | 72.3 | 0.05 | 2.89 | | 81.9 | Example 2-3 |
| Al—Gd | 10.1 | 80.1 | 0.05 | 2.65 | | 80.0 | Example 2-4 |
| Al—Mg | 15.5 | 83.0 | 0.31 | 0.46 | | 12.2 | Com. Ex. 2-1 |
| Al—La | 22.4 | 68.1 | 0.05 | 2.91 | cracking | 67.8 | Com. Ex. 2-2 |
| Al—Ce | 18.7 | 71.7 | 0.05 | 9.44 | no cracking | 70.1 | Com. Ex. 2-3 |
| Al—Eu | 9.8 | 80.4 | 0.44 | 2.44 | | 80.3 | Com. Ex. 2-4 |
| Al—Ta | 15.0 | 75.3 | 0.55 | 1.44 | cracking | 75.1 | Com. Ex. 2-5 |

TABLE 3

| | | | Alkali resistance test | | Humidity |
|---|---|---|---|---|---|
| | | Initial | Dissolu- | | resistance test |
| Target | Film | reflec- | tion | b* after | Reflectance |
| composi- | composi- | tance | rate | test | after test |
| tion | tion | (%) | (nm/sec) | (points) | (%) |
| Al—5Gd | Al—4.1Gd | 85.7 | 0.08 | 0.12 | 85.7 |
| Al—2Gd | Al—1.8Gd | 88.4 | 0.28 | −0.12 | 88.4 |
| Al—5Y | Al—4Y | 86.8 | 0.13 | 0.11 | 86.6 |
| Al—2.5Y | Al—2Y | 86.5 | 0.32 | 0.23 | 86.1 |
| Al—5La | Al—3.6La | 85.5 | 0.13 | 0.16 | 85.5 |

### Experimental Example 4

### (Preparation of Specimens 1 to 32)

Aluminum alloy films having the compositions given in Table 3 were each deposited on a glass substrate (Corning #1737) 20 mm wide and 50 mm long using a DC magnetron sputtering apparatus. A way to carry out the deposition will be illustrated in detail below.

Composite sputtering targets each composed of a pure aluminum sputtering target having a diameter of 101.6 mm and bearing thereon one or more chips of a desired metal element (metal element to be added) were prepared as sputtering targets for deposing the aluminum alloy films and were each attached to an electrode in a chamber of the sputtering apparatus, followed by evacuation to a pressure in the chamber of 1.3×10⁻³ Pa or less. To deposit a pure aluminum film, a pure aluminum sputtering target was used as a sputtering target.

Next, Ar gas was fed into the chamber to give a controlled pressure in the chamber of 2.6×10⁻¹ Pa. Sputtering was then performed while applying a power of 260 W to the sputtering target from a direct-current (DC) power source to carry out deposition of an aluminum alloy film having a desired composition on an entire surface of the substrate. Thus, Specimens 1 to 32 were obtained.

In this process, the compositions of the aluminum alloy films were controlled by changing the type of metal element and number of the chips to be arranged on the pure aluminum sputtering target, whereas the film thickness was controlled to be 150 nm by regulating the deposition time.

Specimens 1 to 32 were each subjected to a compositional analysis, measurement of reflectance immediately after deposition, and warm-water resistance test according to the following methods.

### <Compositional Analysis>

The composition of each specimen aluminum alloy film was measured through ICP emission spectrometry. Specifically, the specimen was dissolved in an acid to give a solution, and the amounts of Al and an added element in the solution were measured through ICP emission spectrometry, and the measured amounts were standardized to 100% and defined as the composition of the aluminum alloy film.

### <Measurement of Reflectance Immediately After Deposition>

The reflectance of each specimen deposited on the glass substrate was measured at wavelengths of from 250 nm to 800 nm, and based on this, a visible light reflectance was calculated in accordance with JIS R 3106.

### <Warm-Water Resistance Test>

Each specimen deposited on the glass substrate (20 mm wide and 50 mm long) was immersed in ion-exchanged water at 30° C. for 30 hours. A sample photograph was taken on the specimen after the immersion with a digital camera, digitalized with an image processing software so that a transparent portion becomes black, the area of the black portion (transparent portion) was determined using an image analysis software, and a film adhesion rate was calculated according to following Formula (1):

Film adhesion rate (%)=100×[20×50−(Area of transparent portion (mm²)]/[20×50] Formula (1)

The reflectance of each specimen after the immersion was measured by the procedure as in the reflectance measurement, and based on this, a rate of reflectance decrease was calculated according to following Formula (2):

Rate of reflectance decrease (%)=100×[(Reflectance immediately after deposition)−(Reflectance after warm-water resistance test)]/(Reflectance immediately after deposition) Formula (2)

### <Alkali Resistance Test>

A predetermined area of each specimen deposited on the glass substrate was masked, and the masked portion (masked area) and a portion not masked (exposed area) were together immersed in a 1 percent by weight KOH aqueous solution for 5 minutes, rinsed with water, and dried, followed by the removal of masking. When the aluminum alloy film dissolved and through which the glass substrate was seen within a time shorter than 5 minutes, the immersion was completed at that point.

After the removal of masking, a level difference between the masked area and the exposed area was measured with a surface profiler (Dektak 6M), and this was defined as a dissolved quantity (nm). A dissolution rate (nm/sec) was then calculated from the immersion time (sec) and the dissolved quantity (nm). Specifically, the dissolution rate was determined according to the formula: (Dissolved quantity)/(Immersion time)=Dissolution rate.

Table 5 shows, of each specimen, the reflectance immediately after deposition, warm-water resistance test results (film adhesion rate and rate of reflectance decrease), and alkali resistance test results.

### <Judgment of Acceptance>

For the reflectance immediately after deposition, a sample having a reflectance of 80% or more was evaluated as “\textcircled{◯}” (excellent), a sample having a reflectance of 55% or more and less than 80% was evaluated as “∘” (good), and a sample having a reflectance of less than 55% was evaluated as “×” (poor).

For the warm-water resistance test, a sample having a film adhesion rate after the warm-water resistance test of 90% or more was evaluated as “\textcircled{◯}”, a sample having a film adhesion rate of 85% or more and less than 90% was evaluated as “∘”, and a sample having a film adhesion rate of less than 85% was evaluated as “×”. A sample having a rate of reflectance decrease after the warm-water resistance test of less than 30% was evaluated as “∘”, a sample having a rate of reflectance decrease of 30% or more and less than 40% was evaluated as “□” (fair), and a sample having a rate of reflectance decrease of 40% or more was evaluated as “×”.

For the alkali resistance test, while defining the dissolution rate of the Al-4.1 atomic percent Gd film (Specimen 30) as a standard (□) a sample having a dissolution rate between that of the Al-4.1 atomic percent Gd film (Specimen 30) and that of the pure aluminum film was evaluated as “∘”, whereas a sample having a dissolution rate of equal to or less than that of the pure aluminum film was evaluated as “×”.

A sample as evaluated “∘” or higher in all the evaluations was accepted herein.

TABLE 4

| | Composition | | | | | | | | | | | | | | | | | | | | | | | | |
|---|---|---|---|---|---|---|---|---|---|---|---|---|---|---|---|---|---|---|---|---|---|---|---|---|---|
| | Group A (atomic percent) | | | | | | | | | | | | | Group B (atomic percent) | | | | | | | | | | | |
| Specimen | Gd | La | Y | Sc | Tb | Lu | Pr | Nd | Pm | Ce | Dy | Ho | Er | Cr | Cu | Ag | Ni | Co | Mn | Si | Mo | V | Fe | Be | Sn |
| 1 | 4.1 | 0 | 0 | 0 | 0 | 0 | 0 | 0 | 0 | 0 | 0 | 0 | 0 | 0.9 | 0 | 0 | 0 | 0 | 0 | 0 | 0 | 0 | 0 | 0 | 0 |
| 2 | 4.1 | 0 | 0 | 0 | 0 | 0 | 0 | 0 | 0 | 0 | 0 | 0 | 0 | 0 | 1.2 | 0 | 0 | 0 | 0 | 0 | 0 | 0 | 0 | 0 | 0 |
| 3 | 0 | 3.8 | 0 | 0 | 0 | 0 | 0 | 0 | 0 | 0 | 0 | 0 | 0 | 1.1 | 0 | 0 | 0 | 0 | 0 | 0 | 0 | 0 | 0 | 0 | 0 |
| 4 | 0 | 3.8 | 0 | 0 | 0 | 0 | 0 | 0 | 0 | 0 | 0 | 0 | 0 | 0 | 0.8 | 0 | 0 | 0 | 0 | 0 | 0 | 0 | 0 | 0 | 0 |
| 5 | 0 | 0 | 4.3 | 0 | 0 | 0 | 0 | 0 | 0 | 0 | 0 | 0 | 0 | 1.6 | 0 | 0 | 0 | 0 | 0 | 0 | 0 | 0 | 0 | 0 | 0 |
| 6 | 0 | 0 | 4.3 | 0 | 0 | 0 | 0 | 0 | 0 | 0 | 0 | 0 | 0 | 0.7 | 0 | 0 | 0 | 0 | 0 | 0 | 0 | 0 | 0 | 0 | 0 |
| 7 | 4.2 | 0 | 0 | 0 | 0 | 0 | 0 | 0 | 0 | 0 | 0 | 0 | 0 | 0 | 0 | 4.4 | 0 | 0 | 0 | 0 | 0 | 0 | 0 | 0 | 0 |
| 8 | 4.2 | 0 | 0 | 0 | 0 | 0 | 0 | 0 | 0 | 0 | 0 | 0 | 0 | 0 | 0 | 0 | 2.5 | 0 | 0 | 0 | 0 | 0 | 0 | 0 | 0 |
| 9 | 4.2 | 0 | 0 | 0 | 0 | 0 | 0 | 0 | 0 | 0 | 0 | 0 | 0 | 0 | 0 | 0 | 0 | 2.6 | 0 | 0 | 0 | 0 | 0 | 0 | 0 |
| 10 | 4.2 | 0 | 0 | 0 | 0 | 0 | 0 | 0 | 0 | 0 | 0 | 0 | 0 | 0 | 0 | 0 | 0 | 0 | 0.9 | 0 | 0 | 0 | 0 | 0 | 0 |
| 11 | 4.2 | 0 | 0 | 0 | 0 | 0 | 0 | 0 | 0 | 0 | 0 | 0 | 0 | 0 | 0 | 0 | 0 | 0 | 0 | 4.3 | 0 | 0 | 0 | 0 | 0 |
| 12 | 4.2 | 0 | 0 | 0 | 0 | 0 | 0 | 0 | 0 | 0 | 0 | 0 | 0 | 0 | 0 | 0 | 0 | 0 | 0 | 0 | 2.2 | 0 | 0 | 0 | 0 |
| 13 | 4.2 | 0 | 0 | 0 | 0 | 0 | 0 | 0 | 0 | 0 | 0 | 0 | 0 | 0 | 0 | 0 | 0 | 0 | 0 | 0 | 0 | 1.6 | 0 | 0 | 0 |
| 14 | 4.2 | 0 | 0 | 0 | 0 | 0 | 0 | 0 | 0 | 0 | 0 | 0 | 0 | 0 | 0 | 0 | 0 | 0 | 0 | 0 | 0 | 0 | 1.3 | 0 | 0 |
| 15 | 0 | 0 | 0 | 3.9 | 0 | 0 | 0 | 0 | 0 | 0 | 0 | 0 | 0 | 2.3 | 0 | 0 | 0 | 0 | 0 | 0 | 0 | 0 | 0 | 0 | 0 |
| 16 | 0 | 0 | 0 | 0 | 4.6 | 0 | 0 | 0 | 0 | 0 | 0 | 0 | 0 | 1.1 | 0 | 0 | 0 | 0 | 0 | 0 | 0 | 0 | 0 | 0 | 0 |
| 17 | 0 | 0 | 0 | 0 | 0 | 3.2 | 0 | 0 | 0 | 0 | 0 | 0 | 0 | 1.1 | 0 | 0 | 0 | 0 | 0 | 0 | 0 | 0 | 0 | 0 | 0 |
| 18 | 4.6 | 0 | 0 | 0 | 0 | 0 | 0 | 0 | 0 | 0 | 0 | 0 | 0 | 0 | 10 | 0 | 0 | 0 | 0 | 0 | 0 | 0 | 0 | 0 | 0 |
| 19 | 4.4 | 0 | 0 | 0 | 0 | 0 | 0 | 0 | 0 | 0 | 0 | 0 | 0 | 0 | 0 | 11 | 0 | 0 | 0 | 0 | 0 | 0 | 0 | 0 | 0 |
| 20 | 4.2 | 0 | 0 | 0 | 0 | 0 | 0 | 0 | 0 | 0 | 0 | 0 | 0 | 3.2 | 0 | 0 | 0 | 0 | 0 | 0 | 0 | 0 | 0 | 0 | 0 |
| 21 | 4.4 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 3.0 | 0 |
| 22 | 0 | 0 | 0 | 0 | 0 | 0 | 4.3 | 0 | 0 | 0 | 0 | 0 | 0 | 0 | 1.9 | 0 | 0 | 0 | 0 | 0 | 0 | 0 | 0 | 0 | 0 |
| 23 | 0 | 0 | 0 | 0 | 0 | 0 | 0 | 3.9 | 0 | 0 | 0 | 0 | 0 | 0 | 1.2 | 0 | 0 | 0 | 0 | 0 | 0 | 0 | 0 | 0 | 0 |
| 24 | 0 | 0 | 0 | 0 | 0 | 0 | 0 | 0 | 4.6 | 0 | 0 | 0 | 0 | 0 | 1.2 | 0 | 0 | 0 | 0 | 0 | 0 | 0 | 0 | 0 | 0 |
| 25 | 0 | 0 | 0 | 0 | 0 | 0 | 0 | 0 | 0 | 5.2 | 0 | 0 | 0 | 0 | 1.2 | 0 | 0 | 0 | 0 | 0 | 0 | 0 | 0 | 0 | 0 |
| 26 | 0 | 0 | 0 | 0 | 0 | 0 | 0 | 0 | 0 | 0 | 3.8 | 0 | 0 | 0 | 1.2 | 0 | 0 | 0 | 0 | 0 | 0 | 0 | 0 | 0 | 0 |
| 27 | 0 | 0 | 0 | 0 | 0 | 0 | 0 | 0 | 0 | 0 | 0 | 4.4 | 0 | 0 | 0.9 | 0 | 0 | 0 | 0 | 0 | 0 | 0 | 0 | 0 | 0 |
| 28 | 0 | 0 | 0 | 0 | 0 | 0 | 0 | 0 | 0 | 0 | 0 | 0 | 4.2 | 0 | 0.6 | 0 | 0 | 0 | 0 | 0 | 0 | 0 | 0 | 0 | 0 |
| 29 | 4.2 | 0 | 0 | 0 | 0 | 0 | 0 | 0 | 0 | 0 | 0 | 0 | 0 | 0 | 0 | 0 | 0 | 0 | 0 | 0 | 16 | 0 | 0 | 0 | 0 |
| 30 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 |
| 31 | 4.3 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 0 | 2.2 |
| 32 | 0.5 | 0 | 0 | 0 | 0 | 0 | 0 | 0 | 0 | 0 | 0 | 0 | 0 | 2.5 | 0 | 0 | 0 | 0 | 0 | 0 | 0 | 0 | 0 | 0 | 0 |

(Remainder being Al and inevitable impurities)

TABLE 5

| | Reflectance | | Warm-water resistance test | | | | | |
|---|---|---|---|---|---|---|---|---|
| | immediately | | | | | Rate of | | |
| | after deposition | | Film adhesion rate | | | reflectance decrease | | |
| | value (%) | Accept/reject | value (%) | Accept/reject | Reflectance | value (%) | Accept/reject | Alkali resistance test |
| 1 | 84.7 | ⊚ | 92.9 | ⊚ | 62.2 | 26.6 | ◯ | ◯ |
| 2 | 86.3 | ⊚ | 87.4 | ◯ | 70.4 | 18.4 | ◯ | ◯ |
| 3 | 84.8 | ⊚ | 95.6 | ⊚ | 60.1 | 29.2 | ◯ | ◯ |
| 4 | 86.1 | ⊚ | 94.4 | ⊚ | 70.0 | 18.7 | ◯ | ◯ |
| 5 | 84.4 | ⊚ | 93.5 | ⊚ | 62.9 | 25.5 | ◯ | ◯ |
| 6 | 87.0 | ⊚ | 93.4 | ⊚ | 73.2 | 15.8 | ◯ | ◯ |
| 7 | 84.9 | ⊚ | 88.4 | ◯ | 60.4 | 28.9 | ◯ | ◯ |
| 8 | 83.7 | ⊚ | 86.3 | ◯ | 58.8 | 29.7 | ◯ | ◯ |
| 9 | 81.6 | ⊚ | 85.4 | ◯ | 61.2 | 25.0 | ◯ | ◯ |
| 10 | 84.2 | ⊚ | 88.9 | ◯ | 59.2 | 29.7 | ◯ | ◯ |
| 11 | 83.1 | ⊚ | 85.1 | ◯ | 59.6 | 28.3 | ◯ | ◯ |
| 12 | 80.2 | ⊚ | 89.9 | ◯ | 59.7 | 25.6 | ◯ | ◯ |
| 13 | 82.4 | ⊚ | 87.3 | ◯ | 58.8 | 28.6 | ◯ | ◯ |
| 14 | 83.6 | ⊚ | 89.2 | ◯ | 60.4 | 27.8 | ◯ | ◯ |
| 15 | 82.5 | ⊚ | 92.2 | ⊚ | 61.1 | 25.9 | ◯ | ◯ |
| 16 | 82.3 | ⊚ | 92.1 | ⊚ | 59.1 | 28.2 | ◯ | ◯ |
| 17 | 86.2 | ⊚ | 91.4 | ⊚ | 64.4 | 25.3 | ◯ | ◯ |
| 18 | 78.9 | ◯ | 85.1 | ◯ | 68.4 | 13.3 | ◯ | ◯ |
| 19 | 75.8 | ◯ | 85.2 | ◯ | 58.8 | 22.4 | ◯ | ◯ |
| 20 | 79.9 | ◯ | 95.6 | ⊚ | 56.2 | 29.7 | ◯ | ◯ |
| 21 | 83.5 | ⊚ | 98.7 | ⊚ | 72.8 | 12.8 | ◯ | ◯ |
| 22 | 84.1 | ⊚ | 89.4 | ◯ | 74.3 | 11.7 | ◯ | ◯ |
| 23 | 85.3 | ⊚ | 91.2 | ⊚ | 68.5 | 19.7 | ◯ | ◯ |
| 24 | 84.2 | ⊚ | 90.4 | ⊚ | 65.5 | 22.2 | ◯ | ◯ |
| 25 | 83.5 | ⊚ | 89.2 | ◯ | 68.0 | 18.6 | ◯ | ◯ |
| 26 | 84.8 | ⊚ | 89.9 | ◯ | 71.1 | 16.2 | ◯ | ◯ |
| 27 | 85.4 | ⊚ | 90.6 | ⊚ | 64.4 | 24.6 | ◯ | ◯ |
| 28 | 85.4 | ⊚ | 91.2 | ⊚ | 62.4 | 26.9 | ◯ | ◯ |
| 29 | 46.5 | X | 96.6 | ⊚ | 44.2 | 4.9 | ◯ | ◯ |
| 30 | 90.5 | ⊚ | 82.8 | X | 51.9 | 42.7 | X | X |
| 31 | 78.8 | ◯ | 24.2 | X | 13.0 | 83.5 | X | ◯ |
| 32 | 86.1 | ⊚ | 87.2 | ◯ | 61.4 | 28.7 | ◯ | X |

Specimens 1 to 17 and 21 to 28 are aluminum alloy films each containing both a Group A element in a content of 2.5 to 6 atomic percent and a Group B element in a content of 15 atomic percent or less, and all of them were found to excel all in reflectance immediately after deposition, warm-water resistance, and alkali resistance. Specifically, they each had a reflectance immediately after deposition of more than 80%, a film adhesion rate after the warm-water resistance test of 85% or more, and a rate of reflectance decrease of 30% or less and showed alkali resistance higher than that of the pure aluminum film.

Specimens 18 to 20 are samples each having a Cu or Ag content of more than 10.0 atomic percent or having a Cr content of more than 3.0 atomic percent and were found to have a somewhat low reflectance immediately after deposition (but evaluated as “∘”), although having excellent warm-water resistance as aluminum alloy films. Specifically, these specimens each had a reflectance immediately after deposition in the range of fmm 75% to 80%, although they had a satisfactory film adhesion rate of 85% or more and a satisfactory rate of reflectance decrease of 30% or less both after the warm-water resistance test.

In contrast, the following specimens not satisfying the conditions specified in the present invention have problems as mentioned below.

Specimen 29 is a sample containing a Group B element in a content of more than 15 atomic percent and was found to have good warm-water resistance but to have a remarkably low reflectance immediately after deposition (less than 50%).

Specimen 30 is a conventional sample of a pure aluminum reflective film and was found to have a very high reflectance immediately after deposition. However, in the warm-water resistance test, this sample was not protected from dissolving out of Al, thereby had a film adhesion rate of less than 85% and a rate of reflectance decrease of more than 30%. This specimen was also found to have poor alkali resistance.

Specimen 31 is a sample containing Sn instead of Group B elements. As compared to the examples according to preferred embodiments of the present invention containing a Group B element, the specimen was found to have a somewhat lower reflectance immediately after deposition (but evaluated as “∘”). In addition, in the warm-water resistance test, this sample was not sufficiently protected fmm dissolving out of Al and thereby had a film adhesion rate of less than 85% and a rate of reflectance decrease of more than 30%.

Specimen 32 is a sample containing a Group B element but containing a Group A element in a content of less than 2.5 atomic percent and was found to have poor alkali resistance, although to have a satisfactory film adhesion rate of 85% or more and a satisfactory rate of reflectance decrease of 30% or less both after the warm-water resistance test.

While the present invention has been described in detail with reference to the specific embodiments thereof, it is obvious to those skilled in the art that various changes and modifications can be made in the invention without departing from the spirit and scope of the invention.

The present application is based on Japanese Patent Application No. 2009-048222 filed on Mar. 2, 2009 and Japanese Patent Application No. 2009-209329 filed on Sep. 10, 2009, the entire contents of which are incorporated herein by reference.

### INDUSTRIAL APPLICABILITY

The aluminum alloy reflective film according to the present invention excels in alkali resistance, acid resistance, and humidity resistance even when bearing no protective film, and is therefore advantageously usable as a reflective film typically for automobile lights, illuminators, and ornamentations without requiring a protective film. In the production process of such products, the aluminum alloy reflective film does not cause decreased productivity due to the formation of protective film and allows the products to have higher durability, thus being useful.

1. An aluminum alloy reflective film, comprising at least one element selected from the group consisting of Gd, La, Y, Sc, Tb, Lu, Pr, Nd, Pm, Ce, Dy, Ho, Er, and Tm in a content of 2.5 to 20 atomic percent, with the remainder consisting of Al and inevitable impurities.

2. The film of claim 1, comprising at least one element selected from the group consisting of Sc, Y, La, Gd, Tb, and Lu in a content of 2.5 to 20 atomic percent.

3. The film of claim 2, comprising at least one element selected from the group consisting of Sc, Y, La, Gd, Tb, and Lu in a content of 2.5 to 6 atomic percent.

4. The film of claim 2, comprising at least one element selected from the group consisting of Sc, Y, La, Gd, Tb, and Lu in a content of more than 6 atomic percent but 20 atomic percent or less.

5. The film of claim 3, comprising at least one element selected from the group consisting of La, Gd, and Y in a content of 2.5 to 6 atomic percent.

6. The film of claim 1, further comprising at least one element selected from the group consisting of Cr, Cu, Ag, Ni, Co, Mn, Si, Mo, V, Fe, and Be in a content of 15 atomic percent or less but more than 0 atomic percent.

7. The film of claim 6, comprising at least one element selected from the group consisting of Gd, La, Y, Sc, Tb, Lu, Pr, Nd, Pm, Ce, Dy, Ho, Er, and Tm in a content of 2.5 to 6 atomic percent.

8. The film of claim 7, comprising Cr in a content of 3.0 atomic percent or less.

9. The film of claim 7, comprising at least one element selected from the group consisting of Cu and Ag in a content of 10.0 atomic percent or less.

10. An automobile light comprising the film of claim 1 as a reflective film.

11. An illuminator comprising the film of claim 1 as a reflective film.

12. An ornamentation comprising the film of claim 1 as a reflective film.

13. An aluminum alloy sputtering target, comprising at least one element selected from the group consisting of Gd, La, Y, Sc, Tb, Lu, Pr, Nd, Pm, Ce, Dy, Ho, Er, and Tm in a content of 2.5 to 35 atomic percent, with the remainder consisting of Al and inevitable impurities.

14. The sputtering target of claim 13, comprising at least one element selected from the group consisting of Sc, Y, La, Gd, Tb, and Lu in a content of 2.5 to 35 atomic percent.

15. The sputtering target of claim 13, further comprising at least one element selected from the group consisting of Cr, Cu, Ag, Ni, Co, Mn, Si, Mo, V, Fe, and Be in a content of 20 atomic percent or less but more than 0 atomic percent.

16. The sputtering target of claim 15, comprising at least one element selected from the group consisting of Gd, La, Y, Sc, Lu, Pr, Nd, Pm, Ce, Dy, Ho, Er, and Tm in a content of 2.5 to 8 atomic percent.

17. The sputtering target of claim 13, which is manufactured through spray forming.
